(19) United States
(12) Patent Application Publication
(10) Pub. No.: US 2023/0133092 A1
(43) Pub. Date: May 4, 2023

(54) SOI STRUCTURED SEMICONDUCTOR SILICON WAFER AND METHOD OF MAKING THE SAME

(71) Applicants: Zing Semiconductor Corporation, Shanghai (CN); Shanghai Institute of Microsystem and Information Technology, Chinese Academy of Sciences, Shanghai (CN)

(72) Inventors: Xing WEI, Shanghai (CN); Rongwang DAI, Shanghai (CN); Ziwen WANG, Shanghai (CN); Minghao LI, Shanghai (CN); Meng CHEN, Shanghai (CN); Hongtao XU, Shanghai (CN)

(73) Assignees: Zing Semiconductor Corporation, Shanghai (CN); Shanghai Institute of Microsystem and Information Technology, Chinese Academy of Sciences, Shanghai (CN)

(21) Appl. No.: 17/586,324

(22) Filed: Jan. 27, 2022

(30) Foreign Application Priority Data
Oct. 29, 2021 (CN) 202111274089.7

(51) Int. Cl. H01L 21/324; H01L 21/762

(52) U.S. Cl. CPC H01L 21/3247; H01L 21/76254

(57) ABSTRACT

A SOI structured semiconductor silicon wafer and a method of making the same is disclosed, comprising: loading a semiconductor silicon wafer in a first batch vertical furnace, and conducting a long-time thermal treatment; conducting a sacrificial oxidation process in a second batch vertical furnace after the long-time thermal treatment; conducting a rapid thermal annealing treatment after the second step ; wherein during the long-time thermal treatment, the semiconductor silicon wafer is kept in a protection atmosphere of pure , heated-up until meet a target temperature after changing the atmosphere of pure argon into a mixture gas of 1-n % Ar and n % H₂, and then annealed in the atmosphere of a mixture of 1-n % Ar and n % hydrogen gas or pure Ar, and n is a value no greater than 10.

### FIELD OF THE INVENTION

The present invention generally relates to a semiconductor manufacture technical field, and specifically, relates to a SOI structured semiconductor silicon wafer and a method of making the same.

### BACKGROUND OF THE INVENTION

As post Moore's law era continues, people harshly demand structure, uniformity and conformity of semiconductor silicon wafers. Nowadays SOI (Silicon on Insulator) is broadly applied in fields of microelectronics, optics and photoelectricity, and faces more challenges in related materials.

Preferably, the thinner top silicon layer of SOI devices is the better, but traditional mechanical polishing has problems of ununiform thickness, great roughness and tendency to introduce surface defects, etc. To replace the traditional mechanical polishing, oftentimes a process of rapid thermal annealing may be performed. However, through an AFM (Atomic Force Microscope) which obtains PSD (Power Spectral Density) from a scanning diagram scanned from a surface of a semiconductor silicon wafer which has been processed with rapid thermal annealing treatment and transformed with FFT (Fast Fourier Transform), it shows that the semiconductor silicon wafer has excessive low frequency intensity. This means rising and falling of the surface in a great range is too great to carry out following process. If a long-time thermal treatment is performed, thermal stress will exist in the top silicon layer and this easily causes slip lines which are harmful to proceed following process.

### SUMMARY OF THE INVENTION

To overcome above-mentioned drawback of the conventional technology, the present invention provides a SOI structured semiconductor silicon wafer and a method of making the same which are capable to decrease surface roughness of a semiconductor silicon wafer to be less than 5 Å and generate no slip lines in an edge.

One aspect of the present invention is to provide a method of making a SOI structured semiconductor silicon wafer, comprising: a first step: loading a semiconductor silicon wafer in a first batch vertical furnace, and conducting a long-time thermal treatment; a second step: conducting a sacrificial oxidation process in a second batch vertical furnace after the long-time thermal treatment; and a third step: conducting a rapid thermal annealing treatment after the second step; wherein during the first step, firstly keep the semiconductor silicon wafer in a protection atmosphere of pure argon, secondly change the atmosphere of pure argon into a mixture gas of 1-n % Ar and n % H₂ and heating-up until meet a target temperature, and then conducting the batch annealing in the atmosphere of a mixture gas of 1-n % Ar and n % H₂ or pure argon, and n is a value not greater than 10.

In an embodiment of the invention, the first batch vertical furnace and the second batch vertical furnace are the same.

In an embodiment of the invention, the long-time thermal treatment in the first step comprises: loading the semiconductor silicon wafer in the first batch vertical furnace, in which a loading temperature range is 500° C.-800° C. and the atmosphere is argon, keeping for 1 min to 10 min; switching the atmosphere to the one of the mixture gas of 1-n % Ar and n % H₂, and heating-up with a rate within 0.5° C./min-20° C./min; and conducting the batch annealing in the atmosphere of the mixture gas of 1-n % Ar and n % H₂ or pure argon for 1 min to 120 min, after heating-up until meet the target temperature which is in the range of 1050° C. to 1250° C.

In an embodiment of the invention, the long-time thermal treatment in the first step comprises: loading the semiconductor silicon wafer in the first batch vertical furnace, in which a loading temperature is 650° C. and the atmosphere is of Ar, keeping for 5 min; switching the atmosphere to the one of the mixture gas of 1-n % Ar and n % H₂, and heating-up with a rate within 0.5° C./min-20° C./min, and n being smaller than 3; and conducting the batch annealing in the atmosphere of the mixture gas of 1-n % Ar and n % H₂ or the one of pure Ar for 30 min to 60 min, after heating-up until meet the target temperature which is in the range of 1100° C. to 1200° C.

In an embodiment of the invention, the sacrificial oxidation process in the second step comprises: oxidizing the semiconductor silicon wafer which has been conducted long-time thermal treatment with a dry oxidation or wet oxidation process according to a predetermined sacrificial oxidation process thickness in an oxidation temperature which is within 800° C. to 1000° C. for a time period depending on the predetermined sacrificial oxidation process thickness; and removing a surface oxide layer of the oxidized semiconductor silicon wafer in a HF aqueous solution which concentration is less than 20%.

In an embodiment of the invention, the rapid thermal annealing treatment in the third step comprises: heating-up the semiconductor silicon wafer, which has been conducted the sacrificial oxidation process, with a rate within 30° C./s-100° C./s in the atmosphere of the mixture gas of 1-n % Ar and n % hydrogen gas of an atmospheric pressure or low pressure; and conducting the batch annealing after heating-up until meet the target temperature within 1100° C. to 1300° C. with a rate within 30° C./s-100° C./s in the same mixture gas of 1-n % Ar and n % hydrogen gas or another atmosphere of pure Ar for 1 s to 120 s.

In an embodiment of the invention, a pressure of the atmosphere is within 1 mbar to 1010 mbar when the mixture gas is of the low pressure.

In an embodiment of the invention, the method further comprises a fourth step: conducting sacrificial oxidation process for the semiconductor silicon which has been conducted the rapid thermal annealing treatment wafer again.

In an embodiment of the invention, the fourth step comprises: after rapid thermal annealing treatment, loading the semiconductor silicon wafer which has been conducted the rapid thermal annealing treatment in the second batch vertical furnace and then conducting the sacrificial oxidation process for the semiconductor silicon wafer which has been conducted the rapid thermal annealing treatment with a dry oxidation, steam oxidation or wet oxidation process according to a target thickness in an oxidation temperature within 800° C. to 1000° C. for a time period depending on the target thickness; and removing a surface oxide layer of the oxidized semiconductor silicon wafer in a HF aqueous solution which concentration is less than 20%.

Another aspect of the present invention is to provide a SOI structured semiconductor silicon wafer, in which surface roughness of a top silicon layer is less than 5 Å and an edge uniformity of the top silicon layer is under ±1%.

Compared with traditional technologies, the present invention has advantages that: after conducting steps in which the semiconductor silicon wafer is planarized in the rising and falling in a great range (low frequency) with long-time thermal annealing treatment; the sacrificial oxidation process is performed after the long-time thermal annealing treatment to release thermal stress due to the long-time thermal annealing treatment and avoid from slip lines shown in a following process; and the semiconductor silicon wafer is planarized in the rising and falling in a small range (high frequency) through rapid thermal annealing treatment, the processed semiconductor silicon wafer may be planarized either in high or low frequency and optimized without traditional chemical mechanical polarizing; the surface roughness of the semiconductor silicon wafer may be lowered and no slip line may be shown in a following manufacturing process.

### BRIEF DESCRIPTION OF THE DRAWINGS

Various objects and advantages of the present invention will be more readily understood from the following detailed description when read in conjunction with the appended drawing, in which:

FIG. 1 shows a non-contact scanning diagram at various steps of the method in an embodiment according to the invention;

FIG. 2 shows PSD curves at various steps of a first implementation according to the invention and that of a second comparative example;

FIG. 3 shows a haze map of a surface of a first comparative example which has been long-time thermal annealed and fast thermal annealed;

FIG. 4 shows a haze map of a surface of the first implementation which has been conducted the long-time thermal annealing treatment, the sacrificial oxidation process and the rapid thermal annealing treatment.

### DESCRIPTION OF EMBODIMENTS OF THE INVENTION

Reference is now made to the following examples taken in conjunction with the accompanying drawings to illustrate implementation of the present invention. Persons of ordinary skill in the art having the benefit of the present disclosure will understand other advantages and effects of the present invention. Obviously, embodiments disclosed here is only exemplary. The present invention may be implemented with other examples. For various view or application, details in the present disclosure may be used for variation or change for implementing embodiments within the scope of the present invention. Please note that the following embodiments and features therein may be combined.

The present disclosure illustrates various aspects of the embodiments according to the present invention, which may be implemented in various ways. Please note that structures and/or functionalities described here is only for description and those skilled in the art should understand that any one of the aspects may be implemented solely or in a combination. For instance, the device and/or method may be implemented in any number or field. Further, other structure and/or functionality may be used to implement the device and/or method.

Please also note that the figures provided here are only exemplary. Only elements relative to the invention are shown therein. Actual number, shape, sizes, type and proportion may be varied in an implementation. Layout or arrangement may be more complicated.

Yet further, the following description provides details for readily understanding the example; however, those skilled in the art will understand how to implement an aspect of the present invention without these specific details.

An embodiment of the present invention provides a method of making a SOI structured semiconductor silicon wafer, adapted to process the SOL comprising three steps. A first step is that: loading a semiconductor silicon wafer in a first batch vertical furnace, and conducting a long-time thermal treatment. Taking a SOI structured semiconductor silicon wafer obtained with Smart-cut™ technology for example, surface roughness of the wafer after peeling is >10 Å. During long-time thermal treatment, the semiconductor silicon wafer may be positioned in a protection atmosphere of pure Ar first, and then heated-up until meet a target temperature in another atmosphere of a mixture gas of 1-n % Ar and n % H₂, and then annealed in the atmosphere of the mixture gas of 1-n % Ar and n % H₂ or the one of pure Ar, and n is a value no greater than 10. The atmosphere of the mixture gas of 1-n % Ar and n % H₂ could not only protect the semiconductor silicon wafer from being oxidized, but also perform a reduction reaction to transform silicon oxide oxidized in the previous process to silicon. As such, the quality of the semiconductor silicon wafer is improved.

A second step is that: sacrificial oxidation process the long-time-thermal-treated semiconductor silicon wafer in a second batch vertical furnace. The semiconductor silicon wafer may be oxidized with a dry oxidation process, wet oxidation process or processes combining dry and wet oxidation according to a predetermined sacrificial oxidation process thickness in an oxidation temperature which is within higher enough to oxidize the semiconductor silicon wafer for a time period depending on the predetermined sacrificial oxidation process thickness.

A third step is that: conducting a rapid thermal annealing treatment to the semiconductor silicon wafer which has been conducted the sacrificial oxidation process. The semiconductor silicon wafer may be heated-up in an atmospheric pressure or low pressure with a heating rate and cooling rate both of which are far greater than those of the long-time thermal annealing treatment in an atmosphere which may be consistent or inconsistent with that of the long-time thermal annealing treatment. The heating rate and cooling rate here may be dozens of times or even thousand times greater than those of the long-time thermal annealing treatment. The surface roughness of the semiconductor silicon wafer after this step is <5 Å.

After the semiconductor silicon wafer is planarized in the rising and falling in a great range (low frequency) with the long-time thermal annealing treatment, conducting the sacrificial oxidation process after the long-time thermal annealing treatment to release thermal stress due to the long-time thermal annealing treatment and avoid from slip lines shown in a following process, and planarized in the rising and falling in a small range (high frequency) through the rapid thermal annealing treatment, the processed semiconductor silicon wafer may be planarized either in high or low frequency realms and optimized without traditional chemical mechanical polarizing; the surface roughness of the semiconductor silicon wafer may be lowered and no slip line may be shown in a following manufacturing process.

In an embodiment, the first batch vertical furnace is the same as the second batch vertical furnace.

When the first and second steps are performed in the same batch vertical furnace, i.e. the steps of long-time thermal annealing treatment and the sacrificial oxidation process are integrated in one furnace, the atmosphere may be filled with pure Ar in the step of annealing first. After the temperature in the batch vertical furnace is lowered to the oxidation temperature, the atmosphere may be arranged to be of gas for oxidation, and the time period may be determined according to a predetermined sacrificial oxidation process thickness. The gas for oxidation may be for dry oxidation, wet oxidation or a combination of dry and wet oxidation.

Specifically, the steps may be implemented in this way that: after the thermal annealing is ended, the atmosphere may be of pure Ar, the temperature may be lowered to the oxidation temperature with a cooling rate which may be within a range of 0.5° C./min-20° C./min, and the temperature may be directly cooled until meet the oxidation temperature which may be within a range of 800° C.-1000° C.; the semiconductor silicon wafer may be oxidized with a dry oxidation, wet oxidation process or processes combining the dry and wet oxidation according to the predetermined sacrificial oxidation process thickness for the time period depending on the predetermined sacrificial oxidation process thickness.

In an embodiment, in the first step, the long-time thermal treatment may comprise steps of: positioning the semiconductor silicon wafer in the first batch vertical furnace, in which a loading temperature is within 500° C.-800° C. and the atmosphere is of Ar, for 1 min to 10 min; switching the atmosphere to the one of the mixture gas of 1-n % Ar and n % H₂ to start heating-up with a heating rate within 0.5° C./min-20° C./min; and after heating to the target temperature which is within 1050° C. to 1250° C., annealing in the atmosphere of the mixture gas of 1-n % Ar and n % H₂ or the one of pure Ar for 1 min to 120 min.

In an embodiment, in the first step, the long-time thermal treatment may comprise steps of: loading the semiconductor silicon wafer in the first batch vertical furnace, in which a loading temperature is 650° C. and the atmosphere is of Ar, for 5 min; switching the atmosphere to the one of the mixture gas of 1-n % Ar and n % H₂ to start heating-up with a heating rate within 0.5° C./min-20° C./min, and n being smaller than 3; and after heating-up until meet the target temperature which is within 1100° C. to 1200° C., annealing in the atmosphere of the mixture gas of 1-n % Ar and n % H₂ or the one of pure Ar for 30 min to 60 min.

In an embodiment, in the second step, the sacrificial oxidation process may comprise steps of: oxidizing the long-time-thermal-treated semiconductor silicon wafer with a dry oxidation or wet oxidation process according to a predetermined sacrificial oxidation process thickness in an oxidation temperature which is within 800° C. to 1000° C. for a time period depending on the predetermined sacrificial oxidation process thickness; and removing a surface oxide layer of the oxidized semiconductor silicon wafer in a HF aqueous solution which concentration is less than 20%.

Dry oxidation may be performed with dried and pure oxygen gas as gas for oxidation, steam oxidation may be performed with highly purified water steam as gas for oxidation, and wet oxidation may be substantial to a combination of the dry and steam oxidation in which a rate of the oxygen gas and steam is within 1 to 3. The predetermined sacrificial oxidation process thickness may be greater than 300 Å.

In an embodiment, the oxidation temperature may be preferred in a range of 900° C.-950° C. After the sacrificial oxidation process, the atmosphere may be switched to be of pure Ar and cooled gradually until meet 500° C. to 800° C., preferably, in 650° C. with the cooling rate which may be within 0.5-20 ° C./min. After thinning, the surface oxide layer of the semiconductor silicon wafer may be removed in the HF aqueous solution, the content of which may be less than 20%, preferably, 5%.

In an embodiment, in the third step, the rapid thermal annealing treatment may comprise steps of: heating-up the semiconductor silicon wafer which has been conducted the sacrificial oxidation process with a heating rate within 30° C./s-100° C./s in the atmosphere of the mixture gas of 1-n % Ar and n % H₂ of an atmospheric pressure or low pressure; and annealing after heating-up until meet the target temperature which is within 1100° C. to 1300° C. with a cooling rate which is within 30° C./s-100° C./s in the same atmosphere of the mixture gas of 1-n % Ar and n % H₂ or another atmosphere of pure Ar for 1 s to 120 s.

In an embodiment, in the third step, the rapid thermal annealing treatment may comprise steps of: processing the semiconductor silicon wafer in an atmospheric pressure or low pressure in which the atmosphere is of the mixture gas of 1-n % Ar and n % H₂ with a heating rate which is within 50° C./s-70° C./s in; and annealing after heating-up until meet the target temperature which is within 1150° C. to 1250° C. with a cooling rate which is within 50° C./s-70° C./s in the same atmosphere of the mixture gas of 1-n % Ar and n % H₂ or another atmosphere of pure Ar for 10 s to 60 s.

In an embodiment, a pressure of the atmosphere is within 1 mbar to 1010 mbar when the atmosphere is of the low pressure.

In an embodiment, a fourth step may be further comprised, which is conducting a sacrificial oxidation process to the semiconductor silicon wafer which has been conducted the rapid thermal annealing treatment again.

The second time of the sacrificial oxidation process in the fourth step is to control the thickness of the top silicon layer on the semiconductor silicon wafer to reach a final target.

In an embodiment, the fourth step may comprise steps of: after rapid thermal annealing treatment, loading the semiconductor silicon wafer which has been conducted the rapid thermal annealing treatment in the second batch vertical furnace and then conducting the sacrificial oxidation process for the semiconductor silicon wafer which has been conducted the rapid thermal annealing treatment with a dry oxidation, steam oxidation or wet oxidation process according to a target thickness in an oxidation temperature within 800° C. to 1000° C. for a time period depending on the target thickness; and removing a surface oxide layer of the oxidized semiconductor silicon wafer in a HF aqueous solution which concentration is less than 20%.

For a SOI structured semiconductor silicon wafer made in above-mentioned embodiment, the surface roughness of the top silicon layer may be less than 5 Å and an edge uniformity of the top silicon layer may be under ±1% to avoid from generating obvious slip lines at the edge of the surface of the semiconductor silicon wafer.

### First Embodiment

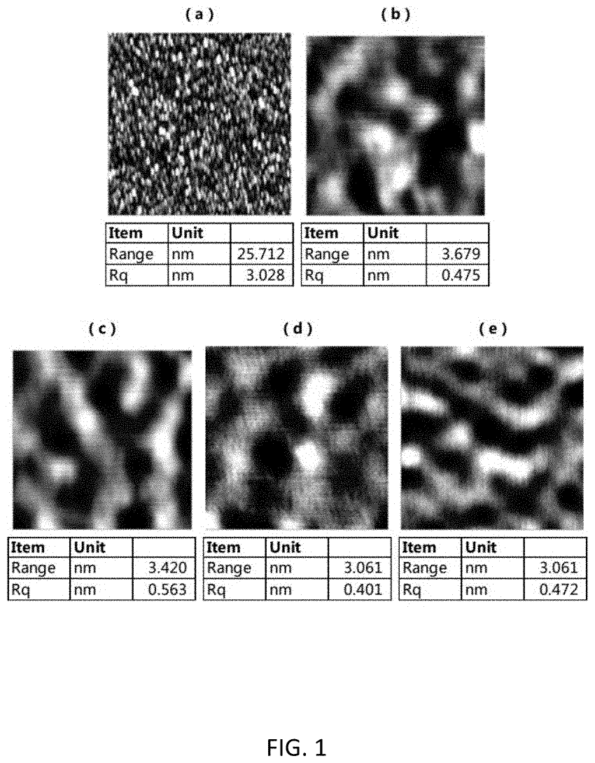

Three pieces of 300 mm SOI wafers made from the same Smart-cut™ process (indicated as first implementation, first comparative example, second comparative example) are taken to do non-contact scanning diagrams. FIG. 1a) shows an AFM 10 μm×10 μm non-contact scanning diagram. From FIG. 1a), it is readily known that surface roughness of all silicon wafers is about 25.7 Å.

Then, the SOI wafers of the first implementation and the first comparative example are loaded into a batch vertical furnace at the same time to be processed with long-time thermal annealing treatment. During the long-time thermal annealing treatment, an initial loading temperature may be 650° C., an atmosphere may be of pure Ar, and the SOI wafers are hold in this process for 5 min. Then, the atmosphere is switched to be of 95% Ar+5% H₂ and heated-up with a heating rate of 5° C./min. After a temperature reaches the target temperature, annealing starts in which the atmosphere is switched to be of pure argon and the temperature is 1100° C. The annealing is processing for 40 min. After the annealing, the atmosphere is switched to be of pure Ar, and the temperature is lowered to 650° C. with a cooling rate of 1-10° C./min.

FIG. 1B) shows an AFM 10 μm×10 μm non-contact scanning diagram of the long-time annealed surfaces of the SOI wafers of the first implementation and first comparative example. From FIG. 1B), it is readily known that surface roughness of all silicon wafers is about 4.8 Å.

After the long-time annealing, the SOI wafer of the first implementation is then oxide-thinned with wet oxidation according to a target thickness at the oxidation temperature of 950° C. The sacrificial oxidation process thickness is 1000 Å.

After the sacrificial oxidation process, the SOI wafer then is rinsed with HF aqueous solution to remove the surface oxide layer. The content of the HF aqueous solution is 5%.

FIG. 1c) shows an AFM 10 μm×10 μm non-contact scanning diagram of the thinned surfaces of the SOI wafer of the first implementation. From FIG. 1c), it is readily known that surface roughness of the thinned silicon wafer is about 5.6 Å.

Then, the SOI wafers of the first implementation, first comparative example and second comparative example are processed with rapid thermal annealing treatment to be heated-up in the atmosphere is of a mixture gas of 95% Ar+5% H₂. During the annealing, the atmosphere is switched to be of pure Ar at an annealing temperature of 1200° C. for the time period of 30 s.

FIG. 1d) shows an AFM 10 μm×10 μm non-contact scanning diagram of the rapid-thermal-annealed surface of the SOI wafer of the first implementation. From FIG. 1d), it is readily known that surface roughness of the thinned silicon wafer is about 4.0 A.

FIG. 1e) shows an AFM 10 μm×10 μm non-contact scanning diagram of the rapid-thermal-annealed surface of the SOI wafer of the second comparative example. From FIG. le), it is readily known that surface roughness of the thinned silicon wafer is about 4.0 Å.

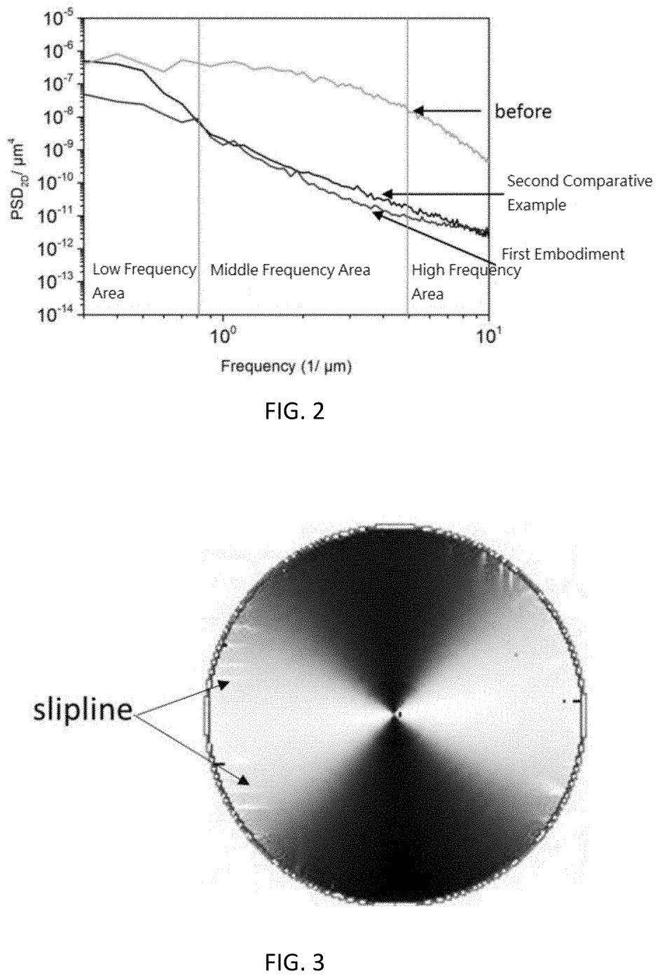

FIG. 2 shows PSD curves at various steps of the first implementation and second comparative example. The curves indicated with before are initial PSD curves of the three samples. The PSD curve of the second comparative example is obtained with a test of rapid thermal processing toward the silicon wafer. From FIG. 2, it is readily known that the whole PSD intensity of the first implementation is lower, especially in the lower frequency realm. Specifically, the PSD in the lower frequency realm is one magnitude lower than that of the second comparative example. This means that the surface of the sample of the first implementation is more flat and thus general performance of the first implementation is better than that of the second comparative example.

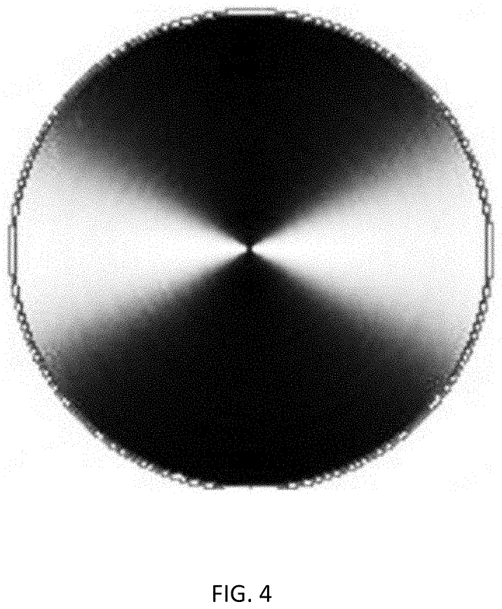

FIG. 3 shows a haze map of a surface of a first comparative example which has been long-time thermal annealed and fast thermal annealed. From FIG. 3, it is readily known that obvious slip lines generate at its edge.

FIG. 4 shows a haze map of a surface of the first implementation which has been conducted the long-time thermal annealing treatment, the sacrificial oxidation process and the rapid thermal annealing treatment. From FIG. 3, it is readily known that no slip line generates at its edge.

Compared with FIGS. 3 and 4, it may be ascertained that the sacrificial oxidation process after the long-time thermal annealing treatment may release residual of thermal stress to avoid from the occurrence of slip lines in the following process.

It is to be understood that these embodiments are not meant as limitations of the invention but merely exemplary descriptions of the invention with regard to certain specific embodiments. Indeed, different adaptations may be apparent to those skilled in the art without departing from the scope of the annexed claims. In all instances, the scope of such claims shall be considered on their own merits in light of this disclosure, and such claims accordingly define the invention(s), and their equivalents or variations, that are protected thereby.

What is claimed is:

1. A method of making a SOI structured semiconductor silicon wafer, comprising:
a first step: loading a semiconductor silicon wafer in a first batch vertical furnace, and conducting a long-time thermal treatment;
a second step: conducting a sacrificial oxidation process in a second batch vertical furnace after the long-time thermal treatment; and
a third step: conducting a rapid thermal annealing treatment after the second step;
wherein during the first step, firstly keep the semiconductor silicon wafer in a protection atmosphere of pure argon, secondly change the atmosphere of pure argon into a mixture gas of 1-n % Ar and n % H₂ and heating-up until meet a target temperature, and then conducting the batch annealing in the atmosphere of a mixture gas of 1-n % Ar and n % H₂ or pure argon, and n is a value not greater than 10.

2. The method according to claim 1, wherein the first batch vertical furnace and the second batch vertical furnace are the same.

3. The method according to claim 1, wherein the long-time thermal treatment in the first step comprises:
loading the semiconductor silicon wafer in the first batch vertical furnace, in which a loading temperature range is 500° C.-800° C. and the atmosphere is argon, keeping for 1 min to 10 min;
switching the atmosphere to the one of the mixture gas of 1-n % Ar and n % H₂, and heating-up with a rate within 0.5° C./min-20° C./min; and
conducting the batch annealing in the atmosphere of the mixture gas of 1-n % Ar and n % H₂ or pure argon for 1 min to 120 min, after heating-up to the target temperature which is in the range of 1050° C. to 1250° C.

4. The method according to claim 3, wherein the long-time thermal treatment in the first step comprises:
loading the semiconductor silicon wafer in the first batch vertical furnace, in which a loading temperature is 650° C. and the atmosphere is of Ar, keeping for 5 min;
switching the atmosphere to the one of the mixture gas of 1-n % Ar and n % H₂, and heating-up with a rate within 0.5° C./min-20° C./min, and n being smaller than 3; and
conducting the batch annealing in the atmosphere of the mixture gas of 1-n % Ar and n % H₂ or pure argon for 30 min to 60 min, after heating-up to the target temperature which is in the range of 1100° C. to 1200° C.

5. The method according to claim 1, wherein the sacrificial oxidation process in the second step comprises:
oxidizing the semiconductor silicon wafer which has been conducted the long-time thermal treatment with a dry oxidation or wet oxidation process according to a predetermined sacrificial oxidation process thickness in an oxidation temperature which is within 800° C. to 1000° C. for a time period depending on the predetermined sacrificial oxidation process thickness; and
removing a surface oxide layer of the oxidized semiconductor silicon wafer in a HF aqueous solution which concentration is less than 20%.

6. The method according to claim 1, wherein the rapid thermal annealing treatment in the third step comprises:
heating-up the semiconductor silicon wafer, which has been conducted the sacrificial oxidation process, with a rate which is within 30° C./s-100° C./s in the mixture gas of 1-n % Ar and n % H₂ of an atmospheric pressure or low pressure; and
conducting the batch annealing after heating-up until meet the target temperature within 1100° C. to 1300° C. with a rate within 30° C./s-100° C./s in the same mixture gas of 1-n % Ar and n % hydrogen gas or another atmosphere of pure Ar for 1 s to 120 s.

7. The method according to claim 6, wherein a pressure of the mixture is within 1 mbar to 1010 mbar when the mixture gas is of the low pressure.

8. The method according to claim 1, further comprising a fourth step:
conducting the sacrificial oxidation process for the semiconductor silicon wafer which has been conducted the rapid thermal annealing treatment again.

9. The method according to claim 8, wherein the fourth step comprises:
after the rapid thermal annealing treatment, loading the semiconductor silicon wafer which has been conducted the rapid thermal annealing treatment in the second batch vertical furnace and then conducting the sacrificial oxidation process for the semiconductor silicon wafer which has been conducted the rapid thermal annealing treatment with a dry oxidation, steam oxidation or wet oxidation process according to a target thickness in an oxidation temperature within 800° C. to 1000° C. for a time period depending on the target thickness; and
removing a surface oxide layer of the oxidized semiconductor silicon wafer in a HF aqueous solution which concentration is less than 20%.

10. A SOI structured semiconductor silicon wafer, wherein surface roughness of a top silicon layer is less than 5 Å no slip line exists in an edge uniformity of the top silicon layer is under ±1%.
